(19) United States
(12) Patent Application Publication
(10) Pub. No.: US 2015/0211110 A1
(43) Pub. Date: Jul. 30, 2015

(54) DEVICE FOR COATING A SUBSTRATE MADE OF PARTICLES

(71) Applicant: TECHNISCHE UNIVERSITÄT WIEN, Vienna (AT)

(72) Inventors: Gerwin Schmid, Vienna (AT); Christoph Eisenmenger-Sittner, Gumpoldskirchen (AT); Johannes Hell, Ober-Grafendorf (AT); Martin Quirchmair, Redlham (AT)

(73) Assignee: TECHNISCHE UNIVERSITAT WIEN, Vienna (AT)

(21) Appl. No.: 14/429,130

(22) PCT Filed: Sep. 13, 2013
(86) PCT No.: PCT/AT2013/050181

§ 371 Date: Mar. 18, 2015

(30) Foreign Application Priority Data
Sep. 21, 2012 (AT) A 50406/2012

(51) Int. Cl. C23C 14/50; H01J 37/34; C23C 14/34

(52) U.S. Cl. CPC C23C 14/505; C23C 14/34; H01J 37/3435; H01J 2237/3323

(57) ABSTRACT

A device (1) for coating a substrate made of particles by means of cathode atomisation with a movable substrate dish (4) tilted relative to the horizontal plane, wherein the substrate dish (4) is arranged loose in a plate (3) which is rotatable about an axis of rotation (10), is tilted and has a side wall (8), wherein an outer wall (19) of the substrate dish (4) is intermittently in contact with the inner side (17) of the side wall (8) of the plate (3).

### TECHNICAL FIELD

The invention relates to a device for coating a substrate made of particles such as grains, granules, powders, chips, rods or fibers, by means of cathode sputtering using a movable substrate dish tilted relative to the horizontal plane.

The cathode sputtering method is a technique applied for the non-destructive coating of, for instance, powdery or granular substrates.

### PRIOR ART

The most widely used variants for obtaining a coating of a substrate as uniform as possible include fluidized-bed coating, hollow-cathode coating and rod-cathode coating. The use of fluidized-bed coating in connection with sputtering is only possible to a limited extent because of the necessary high gas flows. In hollow-cathode coating, the supply and discharge of the substrate, which falls through a vertically arranged hollow cylindrical cathode, involve problems. Rod-cathode coating, in which the substrate is contained in a drum rotating about a horizontal axis of rotation and in whose center the rod cathode is disposed, only allows for low coating rates.

A device of the initially defined kind, which enables coating improved over known methods, was already described by G. Schmid et al., “Optimization of a container design for depositing uniform metal coatings on glass microspheres by magnetron sputtering”, Surface & Coatings Technology 205 (2010), pp. 1929-1936. That device is based on the magnetron sputtering method, which is known per se, wherein, in addition to the electric field (which is a matter of course in sputtering), a magnetic filed is arranged such that the charge carriers circulate in spiral paths above the target surface so as to provide higher ionization and hence higher sputtering rates. The illustrated device comprises a tilted substrate dish arranged opposite and below the target. By rotating the substrate dish, the contained substrate is thoroughly mixed and the particles are prevented from sticking together or to the container wall. The coating of glass microspheres tested in the cited article is particularly sophisticated because of the hollow glass spheres being mechanically more sensitive and small particles, in general, tending more strongly to agglutinate than other, e.g. massive, substrates—due to their low densities.

U.S. Pat. No. 6,355,146 shows a coating method using magnetron sputtering, wherein a substrate dish either oscillates by the aid of piezo-elements or is rotated in the manner of a paddlewheel.

U.S. Pat. No. 6,038,999 A1 shows a coating device comprising a reception chamber inclined by 15° for a substrate consisting of loose parts. There, shaking of the substrate is achieved by rotating the chamber and, optionally, by additionally using stirrers.

The substrate container shown in JP 11241157 A rotates about an inclined axis and comprises a screen or basket immovably connected to the container. Blending of the substrate is achieved by interrupting and reversing the rotational movement.

### SUMMARY OF THE INVENTION

It is the object of the invention to propose a device of the initially defined kind, which enables—in a constructionally most simple manner—both the prevention, or at least further reduction, of an agglutination of the substrate and the detachment of the substrate from the dish. The invention is based on the idea to impart shock-like vibrations to the substrate dish. Since the invention aims at the coating of substrates in the micrometer range (particle sizes of 4-1000 μm), an oscillation of the substrate dish is to be largely avoided, since this would frequently result in a compaction of the substrate and, consequently, in an increased agglutination. Finally, the invention is to be compatible with the low gas pressures required for magnetron sputtering.

This object is achieved by a device according to the invention of the initially defined kind in that the substrate dish is loosely arranged in a tilted plate that is rotatable about an axis of rotation and has a side wall, wherein an outer wall of the substrate dish is intermittently in contact with the inner side of the side wall of the plate.

Due to its loose arrangement, the substrate dish is freely movable in a plane of the plate extending perpendicular to the axis of rotation of the plate, and it can thus be displaced within the plate and rotated relative to the plate, its free movement being limited by the side wall of the plate. Due to the tilt of the plate, a movement of the substrate dish within, and relative to, the plate is enforced by gravity during rotation, and vibrations will be caused whenever the substrate dish hits the side wall of the plate during such movement. This can, for instance, be promoted in that the plate and the substrate dish have different contour shapes, for instance if the substrate dish is round/oval and the plate is polygonal (in top view). The braking force exerted on the substrate dish by the side wall is also propagated to substrate particles located adjacent the wall of the dish, thus causing their detachment from the wall under the effect of force components acting parallel to the inner side of the substrate dish.

A rotating movement of the substrate dish alternating with periodic vibrations can be achieved in a simple manner in that both the outer wall of the substrate dish and the side wall of the plate are cylinder-shaped with the cylinder axes extending in parallel so as to make the substrate dish roll off within the plate at least in sections, and that the side wall of the plate comprises at least one tappet member for the substrate dish on the inner side. Because of the cylindrical shapes and the parallel axes of the two containers, the smaller substrate dish in the larger plate due to gravity will always move to the deepest point of the plate as the latter is being rotated. In order to ensure rolling (rather than sliding) of the dish within the plate so as to cause a constant circulation of the contents of the dish, it will be advantageous if a certain frictional engagement or adherence is provided between the outer wall of the substrate dish and the inner side of the side wall of the plate, which can, for instance, be achieved by an adequate material roughness. As soon as the substrate dish strikes a tappet member, the rolling movement is interrupted and the substrate dish is moved along with the plate, and lifted in the plate, until the center of gravity of the dish and its contents is shifted via the tappet member. The substrate dish will then roll over the tappet member and roll, fall or slide down within the plate due to gravity until it touches the inner side of the plate wall and is shaken by the sudden impact. Due to the relative movement within the plate, the substrate dish is rotated by more than 360° during a complete revolution of the plate.

In respect to the tappet member, it has turned out to be advantageous if the latter is formed by a radially inwardly protruding projection, wherein the height (length) of the projection is smaller than the difference between the inner radius of the plate and the outer radius of the substrate dish. The height of the projection determines how far the substrate dish is taken along from the deepest point during the rotation of the plate, wherein rolling-off of the substrate dish over the tappet member, i.e. the projection, is only possible at a correspondingly small height of the tappet member. In a preferred manner, the height of the projection is between 10 and 20% of the outer radius of the substrate dish, since the dish will thus be taken along within the plate in the direction of rotation at an angle of about 25° to 35°. With a corresponding “height of fall”, the extent of vibration will constitute a suitable compromise between the effective removal of agglutinations and a low mechanical load on the substrate.

In order to enable adjustment of the severity or extent of the vibrations, it will be beneficial if the tappet member is radially adjustable. The device can thus be optimally adapted to the respective requirements, i.e. as a function of the substrate, its density, mechanical stability and aggregation properties, the coating material, the temperature etc. If several tappet members are provided, different vibration strengths can, moreover, be set.

A simple and effective option to produce such a tappet member is provided in that the tappet member is formed by a screw passing through the side wall of the plate. The constructive expenses for the production of the device will thus be minimized while an continuous adjustability of the vibration is at the same time provided. The screws can be simply inserted, removed or replaced on demand. Yet, also other forms of tappet members such as ramps, wedges or blades are, of course, conceivable to achieve a comparable effect.

For the cylindrical shapes described above, it will be beneficial if the plate-to-substrate-dish diameter ratio is about 13:9. This ratio, i.e. if the diameter of the substrate dish amounts about 70% of the diameter of the plate, provides sufficient flexibility for dimensioning the tappet member with a view to enabling a suitable vibration of the substrate dish to be achieved for most of the substrates while, at the same time, avoiding an excessive increase in the space required for the device by a comparatively large plate.

As regards the material of the substrate dish, it will be advantageous if the mass of the dish is as low as possible since this will cause a stronger vibration of its contents at an identical impact speed. Since the substrate dish, in addition, is to be electrically conductive and mechanically resistant and has to withstand the temperatures usually applied in cathode coating, it will be beneficial if the substrate dish is made of aluminum, which is, moreover, easy to work as compared to other materials.

The angle of inclination of the plate and the substrate dish is decisive for the acceleration of the substrate dish within the plate, and hence also for the degree of vibration during the impact on the side wall of the plate. Too large a tilt angle may, however, result in the escape of substrate from the dish, in particular during the impact, and therefore limits the amount of substrate to be coated present in the substrate dish. Under these considerations, tilt angles ranging between 14° and 75°, preferably between 45° and 50°, have proved to be particularly suitable.

For an effective blending of the substrate it will, furthermore, be beneficial if an inner wall of the substrate dish in a radially outer portion is designed to taper from the opening in a funnel-shaped fashion and in a radially inner portion is designed to conically taper to the opening, so that a transition between the two thus formed conical portions forms the lowest zone of the substrate dish. The advantage of this structure resides in the interaction with the tilt or inclination of the substrate dish, since thereby each inner surface of the dish will at least temporarily be at least approximately in the perpendicular during a complete revolution, thus enabling the substrate to slide down in an optimal manner. In the described structure, the transition between the outer, funnel-shaped portion and the inner, conical portion is preferably located approximately at half an inner radius of the substrate dish, the tilt angles of the two portions relative to a plane extending perpendicular to the axis of rotation being about 45° and −45°, respectively. The radial extension of the inner side of the dish follows a rectangular isosceles triangle such that, in the inclination, each “vertical” portion of the inner surface is located opposite an approximately equally long “horizontal” portion and the sliding-down substrate is collected to the optimal extent.

For an additional thorough mixing and for breaking-up of possible substrate agglomerations, at least one mixing element, preferably in the form of a fin, may be arranged on the inner wall of the substrate dish. It has, in particular, been found that a fin arranged tangentially in the direction of rotation will ensure a good mingling effect at a simultaneously low additional adherence of substrate to the fin. By such an arrangement, disadvantageous scooping of the substrate will be avoided.

### BRIEF DESCRIPTION OF THE DRAWINGS

In the following, the invention will be explained in more detail by way of particularly preferred exemplary embodiments, to which it is, however, not to be restricted, and with reference to the drawing. In the drawing, in detail:

FIG. 1 depicts a lateral sectional view through a device according to the invention, which is shown along with a target and a drive unit;

FIG. 2 depicts a direct top view of the device according to the invention along the axis of rotation of the plate;

FIG. 3 illustrates a detail of FIG. 1 showing but the present device;

FIG. 4 illustrates the sequence of movements of the substrate dish in the plate during a rotation of the plate by approximately 120° by way of five positions in the manner of snapshots;

FIG. 5 is a schematic cross-sectional view of a round particle or microsphere before and after coating;

FIG. 6 is a schematic cross-section view of an edged particle before and after coating; and

FIG. 7 is a schematic cross-section view of a rod-shaped particle before and after coating.

### DETAILED DESCRIPTION OF THE DRAWINGS

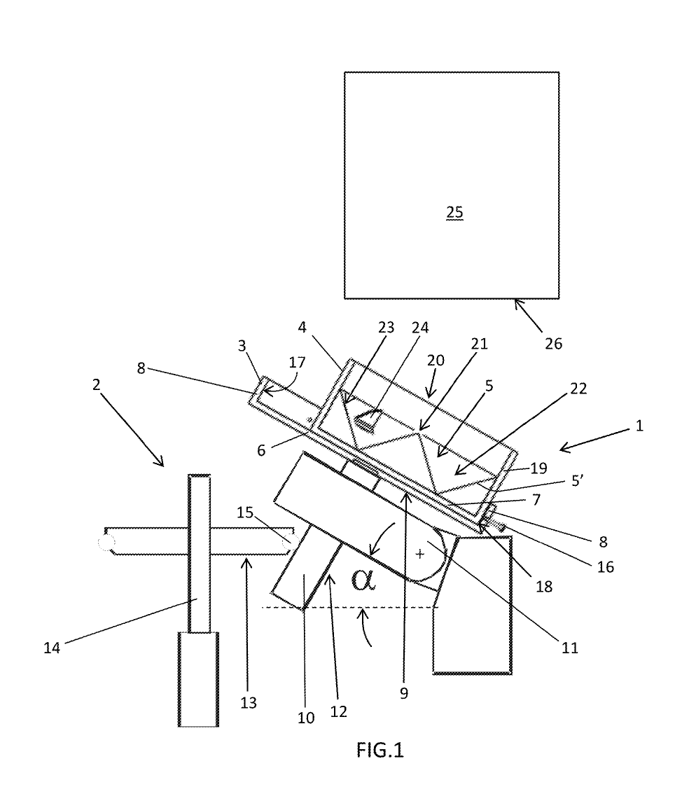

In FIG. 1, a preferred exemplary embodiment of the device 1 according to the invention arranged in connection with a drive unit 2 is shown.

The device 1, as is also apparent from FIG. 3, is substantially comprised of two containers 3, 4 arranged one within the other and open to one side. The inner container 4, which is also referred to as inner dish, substrate dish, or just dish, is designed like a pot or drum, having portions each with a conical or funnel-shaped inner side or bottom shape 5. In operation, the material to be coated (not illustrated), e.g. a substrate, is contained in the dish 4 as illustrated in FIGS. 5 to 7. The inner container 4 is smaller than the outer container 3 and, in FIG. 1, is loosely arranged in the outer, larger container 3, which is also referred to as outer dish or—for better distinction—plate. In the illustrated example, both the plate 3 and the dish 4 have a plane bottom 6 or 7, respectively, such that the (outer) bottom 7 of the dish 4 completely abuts the (inner) bottom 6 of the plate 3. During a movement of the plate 3, the bottom 7 of the dish 4 is thus able to slide over the bottom 6 of the plate. The side wall 8 of the plate 3 prevents the substrate dish 4 from falling or slipping out of the plate 3 because of its tilt.

The plate 3 according to FIG. 1 is connected to a rotating shaft centrally at its bottom side 9. The rotating shaft 10 is mounted in a pivotable cantilever arm 11 of the drive unit 2 while passing through the same so as to enable the adjustment of the tilt angle of the plate 3 by pivoting the cantilever arm 11. On a rear side 12 of the cantilever arm 11, which is located opposite the plate 3, the rotating shaft 10 is, for instance, connected to a friction wheel drive 13 whose shaft 14 is connected to a motor (not illustrated) arranged outside the vacuum chamber and which comprises an O-ring-shaped friction ring 15. A rotation of the friction wheel drive 13 therefore causes a rotation of the tilted plate 3 about the axis of the shaft 10. If the tilt angle of the plate 3 is changed by releasing the respective cantilever arm 11 and altering its angle a, the friction wheel drive 13 can optionally be adapted accordingly, wherein the height of the O-ring 15 is adjusted such that the contact between the O-ring 15 of the friction wheel drive 13 and the rotating shaft 10 of the plate will be maintained.

In the side wall 8 of the plate 3, a screw 16 is to be seen (cf. FIG. 3), which is radially turned out to such an extent that it does not rise above the inner side 17 of the side wall 8. As a result, the screw 16 in the state illustrated here does not form a tappet member, thus allowing the dish 4 to slide within the plate 3 to the deepest point 18, where the outer wall 19 of the dish 4 is in contact with the inner side 17 of the side wall 8 of the plate 3. The side wall 8 of the plate 3 only reaches to approximately one third of the height of the outer wall 19 of the substrate dish 4, which is completely sufficient at the preferred tilt angles of 14° to 75°, in particular 45° to 50°, in order to prevent the dish 4 from falling out of the plate 3.

The inner wall 5′ of the substrate dish 4 below a defined height tapers downwardly in a funnel-shaped manner from outside to approximately half the radius, i.e. from the opening 20 to the bottom 7, and, inversely, from half the radius rises inwardly from the bottom 7 to the opening 20 in a conical manner as far as to the center 21. It thus forms an annular depression 22 with a triangular cross section. In the outer, funnel-shaped portion 23, a mixing element 24 in the form of a fin is tangentially arranged in the direction of rotation.

Above the dish opening 20 is arranged, in a manner known per se, a target 25 from whose surface 26 the coating material is stripped by magnetron sputtering in a usual manner—which is therefore not to be described in detail here—and applied to the substrate dish 4 and the substrate, respectively. The substrate dish 4, which is made of aluminum and hence conductive, is usually connected to ground via the plate 3 and the drive unit 2. The wall thickness of the dish 4 can, for instance, be about 3 mm.

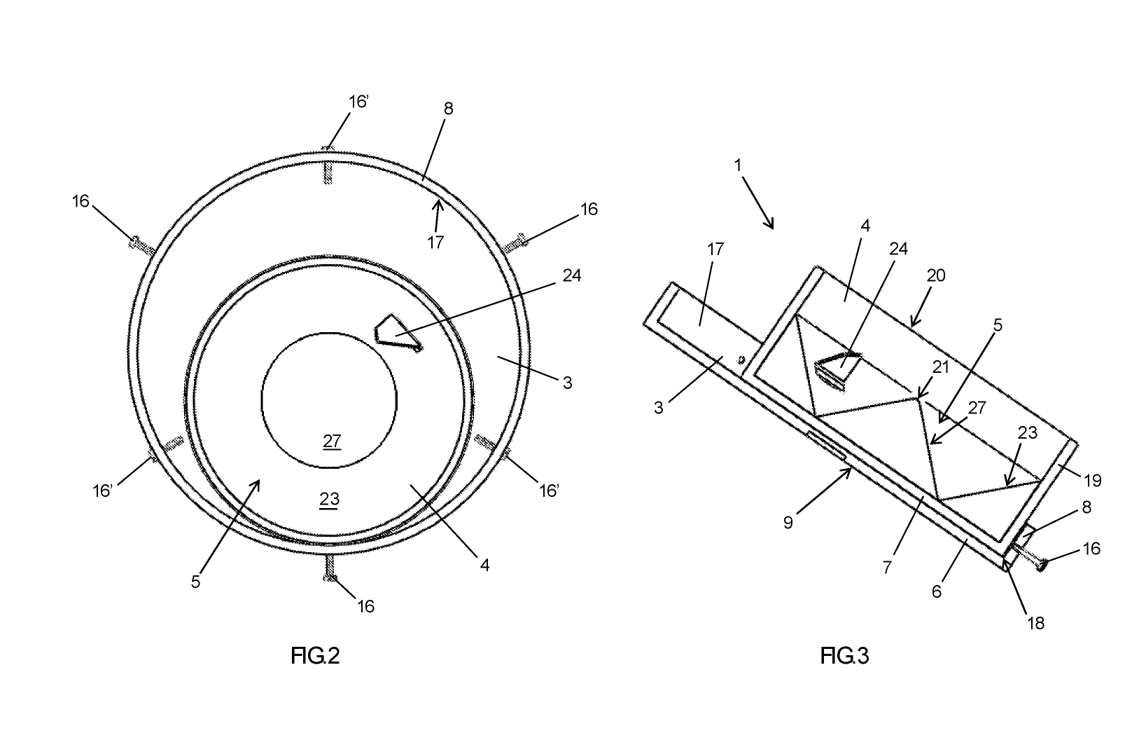

FIG. 2 is a top view of the device 1, from which the different diameters of the substrate dish 4 and the plate 3 are apparent. In this example, six screws 16 are arranged at regular angular distances in the side wall 8 of the plate 3, passing through the side wall 8. Only three screws 16 are sufficiently turned through the side wall 8 so that they project radially inwardly from the inner side 17, thus forming tappet members 16′. Since these three screw tappet members 16′ are completely screwed in here, they have maximum heights. From the top view of the substrate dish 4 depicted in FIG. 2, the segmentation of the inner side 5 into a radially outer, funnel-shaped portion 23 and a radially inner, conical portion 27 as well as the arrangement of the fin 24 in the radially outer portion 23 are, moreover, apparent.

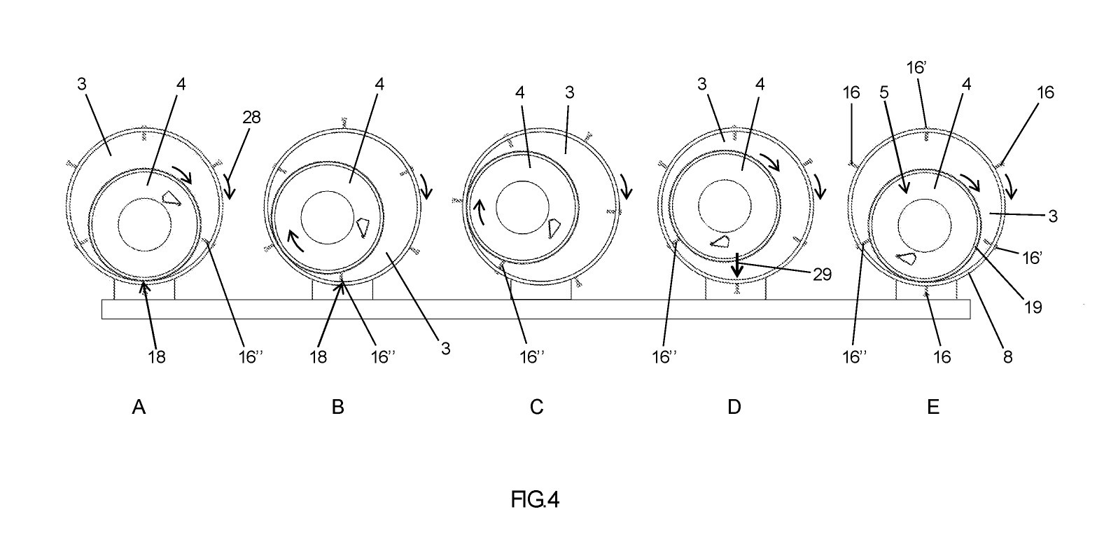

The sequence of movements of the substrate dish 4 in the plate 3 during a partial revolution of the plate 3 is schematically illustrated in FIG. 4 plus Subfigures A-E in oblique views. FIG. 4A corresponds to the above-described position represented in FIGS. 1-3, wherein the substrate dish 4 is located at the deepest point 18 of the plate 3. When the plate 3 is clockwisely rotated by approximately 60°, starting from FIG. 4A, the position illustrated in FIG. 4B will result. In doing so, the dish 4 was taken along by a screw 16″ and raised from the deepest point 18 of the plate 3 while being rotated. The center of gravity of the dish 4 plus its contents yet is still on the same side of the tappet member 16″ as in FIG. 4A.

This changes at a further rotation of the plate 3 by about 30°, whereupon the position depicted in FIG. 4C will be reached. The dish 4 was again respectively rotated further, starting to roll off over the tip of the screw 16″.

In the situation according to FIG. 4D, the dish 4 has almost completely rolled over the screw 16″ and, due to gravity, undergoes an acceleration (arrow 29) downwards and along the plate bottom 6, with which it is still in contact.

In FIG. 4E, the dish 4 has reached the side wall 8 of the plate 3 and is braked. The sudden braking triggers a vibration of the dish 4 and the substrate as in case of an impact on the outer wall 19 of the dish 4.

From the described sequence, it becomes clear that the height of the tappet member 16″ determines the angle at which the center of gravity of the dish 4 travels over the tip of the tappet member 16″, and hence the height of fall and the vibration during the impact.

On the assumption of a constant angular speed of the plate 3, the described procedure will be repeated in the illustrated example at a complete revolution of the plate 3 for each of the screws 16, 16′, 16″, i.e. a total of three times, since the height of all three screws 16, 16′, 16″ is identical. If vibrations of different intensities are desired, it is possible to adjust the screws 16, 16′, 16″ to different heights. It will be beneficial to take care that the arrangement of the screws 16, 16′, 16″ and the diameter ratio of the dish 4 and the plate are chosen such that vibrations will occur in as many different positions as possible of the dish 4. A dish 4 that would periodically always hit the same point(s), on the one hand could, in the long term, result in a damage to the dish 4, and on the other hand implies that some zones of the inner side 5 are less affected than others by the detachment effect of the vibration.

To illustrate the uniform coating achieved, FIGS. 5-7 depict examples of uncoated and coated substrates having different structures, each side by side.

FIG. 5A schematically shows an uncoated microsphere 30 similar to hollow glass microspheres or bullet-proof glass spheres. Following coating in a device 1, the microsphere 30 depicted in FIG. 5B is wrapped in a layer 31 of the target material, which has a uniform thickness.

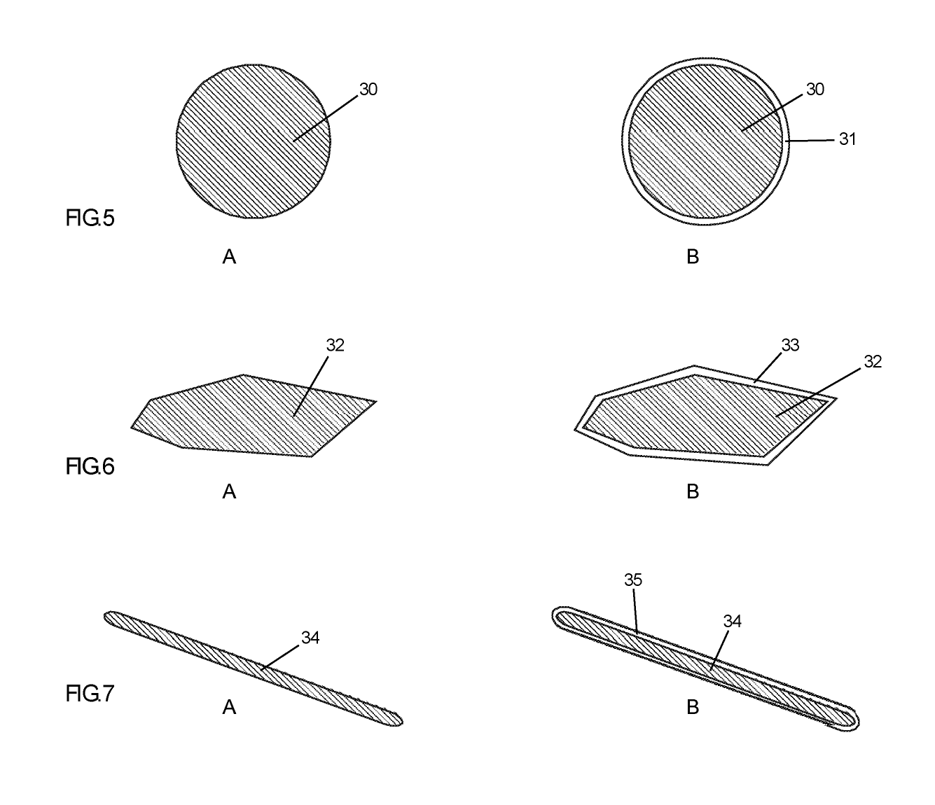

A comparable result can also be achieved for an edged particle or granules like diamonds or tungsten carbide particles according to FIG. 6A. Although the respective coating 33 depicted in FIG. 6B shows slight irregularities, it likewise provides complete wrapping of the substrate 32.

The uniform coating of microfibers, e.g. carbon fibers, or fiber-shaped or rod-shaped substrates like the fiber 34 depicted in FIG. 7A can also be achieved by the device 1 without any substantial agglutination of the substrate or between the substrate and the substrate dish 4. The coated fiber 34 according to FIG. 7A, which is depicted in FIG. 7B, comprises an enveloping layer 35 of the target material.

After coating, the substrate in all cases has a uniform surface consisting of the selected target material.

In addition to the illustrated examples of a round dish 4 and a round plate 3, other shapes are, of course, also conceivable. Thus, an experiment was, for instance, made with a square plate shape, the plane side walls functioning in a manner similar to the tappet members. In this case, the dish always moves to the deepest corner of the plate. When the plate is rotated, with the dish being carried along, and another corner reaches a deeper point than that where the dish is positioned, the dish will slide or roll to this new corner along the connecting side wall and there will impinge on the side wall extending perpendicular thereto, thus causing the vibration according to the invention. However, round containers 3, 4 are generally simpler and more economical to produce, which is why they have been described as preferred embodiments.

1-11. (canceled)

12. A device for coating a substrate of particles by means of cathode sputtering comprising a movable substrate dish tilted relative to a horizontal plane, wherein the substrate dish is loosely arranged in a tilted plate that is rotatable about an axis of rotation and has a side wall, wherein an outer wall of the substrate dish is intermittently in contact with an inner side of the side wall of the plate.

13. The device of claim 12, wherein both the outer wall of the substrate dish and the side wall of the plate are cylinder-shaped with cylinder axes extending in parallel so as to make the substrate dish roll off within the plate at least in sections, and the side wall of the plate comprises at least one tappet member for the substrate dish on the inner side.

14. The device of claim 13, wherein the tappet member is formed by a radially inwardly protruding projection having a height that is smaller than a difference between an inner radius of the plate and an outer radius of the substrate dish.

15. The device of claim 14, wherein the height of the projection is between 10 and 20% of the outer radius of the substrate dish.

16. The device of claim 13, wherein the tappet member is radially adjustable.

17. The device of claim 13, wherein the tappet member is formed by a screw passing through the side wall of the plate.

18. The device of claim 13, comprising a plate-to-substrate-dish-diameter ratio of about 13:9.

19. The device of claim 12, wherein the substrate dish is comprised of aluminum.

20. The device of claim 12, having a tilt angle of the plate and the substrate dish of between 14° and 75°.

21. The device of claim 20, wherein the tilt angle of the plate and the substrate dish is between 45° and 50°.

22. The device of claim 12, wherein an inner wall of the substrate dish in a radially outer portion is designed to taper from an opening in a funnel-shaped fashion, and in a radially inner portion is designed to conically taper to the opening, so that a transition between the two thus formed conical portions forms a lowest zone of the substrate dish.

23. The device of claim 22, wherein the transition between the outer, funnel-shaped portion and the inner, conical portion is located approximately at half an inner radius of the substrate dish, with tilt angles of the two portions relative to a plane extending perpendicular to an axis of rotation being about 45° and −45°, respectively.

24. The device of claim 12, wherein at least one mixing element is arranged on the inner wall of the substrate dish.

25. The device of claim 24, wherein the at least one mixing element is a fin.
